(19) United States
(12) Patent Application Publication
(10) Pub. No.: US 2011/0084356 A1
(43) Pub. Date: Apr. 14, 2011

(54) LOCAL BURIED LAYER FORMING METHOD AND SEMICONDUCTOR DEVICE HAVING SUCH A LAYER

(75) Inventors: Eero Saarnilehto, Tutku (FI); Jan Sonsky, Leuven (BE)

(73) Assignee: NXP B.V., Eindhoven (NL)

(21) Appl. No.: 12/995,764

(22) PCT Filed: May 20, 2009
(86) PCT No.: PCT/IB2009/052108

§ 371 Date: Dec. 2, 2010

(30) Foreign Application Priority Data
Jun. 2, 2008 (EP) 08157412.1

(51) Int. Cl. H01L 29/06; H01L 21/762

(52) U.S. Cl. 257/506; 438/404; 257/E21.545; 257/E29.02

(57) ABSTRACT

The present invention discloses a method of forming a local buried layer (32) in a silicon substrate (10), comprising forming a plurality of trenches (12, 22) in the substrate, including a first trench (22) having a width preventing sealing of the first trench in a silicon migration anneal step and at least one further trench (12) connected to the first trench; exposing the substrate (10) to said anneal step, thereby converting the at least one further trench (12) by means of silicon migration into at least one tunnel (16) accessible via the first trench (22); and forming the local buried layer (32) by filling the at least one tunnel (16) with a material (26, 28, 46) via the first trench (22). Preferably, the method is used to form a semiconductor device having a local buried layer (32) comprising a doped epitaxial silicon plug (26), said plug and the first trench (22) being filled with a material (28) having a higher conductivity than the doped epitaxial silicon (26).

### FIELD OF THE INVENTION

The present invention relates to a method of forming a local buried layer in a silicon substrate. The present invention further relates to a semiconductor device having a local buried layer.

### BACKGROUND OF THE INVENTION

Nowadays, complex semiconductor devices, e.g. integrated circuits, are being manufactured that have substantially different functionality combined on a single die. The different functionality may require the manufacture of structures in different process technologies on the die. This typically requires complex manufacturing processes.

An example of such a process is the so-called BCD (Bipolar-CMOS-DMOS) process, which classifies the family of silicon processes that allows the integration of different structures such as bipolar structures for precise analog functions, CMOS structures for digital design and DMOS structures for power and high voltage applications on the same chip. To enable the integration of these different structures, BCD technology makes use of a number of buried layers. The formation of these buried layers makes the technology complicated and rather expensive compared to baseline CMOS technology.

The buried layers may be used for different purposes. For instance, a buried oxide layer provides vertical isolation, whereas a buried heavily doped layer acts as a buried low-ohmic terminal, which for instance may be used in conjunction with vertical high voltage and bipolar devices fabricated in BCD technologies.

Another example of such a process is the so-called ABCD process of NXP Semiconductors, which is a BCD process built on a silicon-on-insulator (SOI) wafer for full dielectric isolation. The SOI approach has attracted interest for many years now because of the advantages offered in reducing parasitic effects between integrated functions. However, a significant drawback of any SOI process is the high manufacturing cost and complexity, which means that SOI processes are currently only used for dedicated high-end products.

Recently, several methods have been published for fabricating local SOI islands in a substrate. For instance, U.S. patent application No. 2003/0168711 A1 discloses a method of forming an SOI wafer, in which a plurality of trenches are formed in a silicon wafer. The cavities are subsequently sealed in an epitaxial growth step. Then the trenches are reshaped in an anneal step in a deoxidizing atmosphere, after which a second masked trench is etched that provides access to the reshaped trenches and delimits a monocrystalline silicon region. The partition walls of the reshaped trenches and the walls of the second masked trench are subsequently oxidized and the trenches filled with an oxide to convert a predefined part of the substrate into a SOI type structure. A drawback of this method is that several etching steps are required to form the buried oxide region, which adds to the complexity and cost of the process.

An alternative process is described in U.S. Pat. No. 7,019,364 B1. A plurality of parallel trenches is formed in a semiconductor substrate, with the trenches spaced apart no more than 0.8 μm. A final trench in the series of trenches is wider than the other trenches. Next, the substrate is exposed to an anneal step in a non-oxidizing atmosphere under a reduced pressure (10 Torr) at 1100° C. This triggers silicon migration from the trench side walls to the openings of the trenches, thereby sealing as well as merging these trenches, thus forming a buried void in the substrate. However, the final trench is not sealed because of the larger width of this trench, such that the buried void can be accessed via the final trench because the partition wall between the final trench and the buried void has migrated during the anneal step, thus connecting the buried void to the final trench, after which a silicon oxide film is formed inside the buried void and the final trench. A drawback of this method is that it is difficult to form buried voids having a small width connected to the final trench.

The present invention is aimed at solving the above-mentioned disadvantages and/or drawbacks.

### SUMMARY OF THE INVENTION

The present invention provides a method of forming a local buried layer in a silicon substrate that simplifies the formation of small width buried layers.

The present invention further provides a semiconductor device having such a buried layer.

### DETAILED DESCRIPTION OF THE INVENTION

According to an aspect of the present invention, there is provided a method of forming a local buried layer in a silicon substrate, comprising forming a plurality of trenches in the substrate, including a first trench having a width preventing sealing of the first trench in a silicon migration anneal step and at least one further trench connected to the first trench; exposing the substrate to said anneal step, thereby converting the at least one further trench by means of silicon migration into at least one tunnel accessible via the first trench and forming the local buried layer by filling the at least one tunnel with a material via the first trench.

The provision of a trench network in which a number of narrow trenches, i.e. trenches that can be sealed in an anneal step, are connected to at least one wide trench, i.e. a trench that is too wide to be sealed in such an anneal step, makes it possible to form a wide variety of buried structures in the semiconductor substrate, including relatively narrow channels that are formed by a single further trench. Alternatively, by limiting the spacing between multiple further trenches, a single buried cavity may be formed by the migration of the side wall material between these trenches to the trench openings during the anneal step, such that a single buried cavity accessible via the first trench is formed. A combination of small channels and wider cavities can also be formed this way. Hence, the method of the present invention facilitates the manufacturing of a wide variety of buried layers simply by variation of the spacing between the further trenches.

The anneal step may comprise annealing the silicon substrate in a reduced pressure non-oxidizing atmosphere such as a hydrogen ambient, which has been demonstrated to yield good silicon migration results.

The plurality of trenches may be formed by depositing a hard mask over the substrate, patterning the hard mask, exposing the substrate to a reactive ion etch and removing the hard mask. This provides excellent control over the feature size of the trenches.

In a preferred embodiment, the step of forming the local buried layer comprises at least partially filling the at least one tunnel with a doped epitaxial silicon. This is based on the realization that an epitaxial silicon can be grown selectively, e.g. in the one or more tunnels formed during the anneal step. The substrate may be subsequently submitted to a thermal budget to ensure an even distribution of the dopant, e.g. an n-type dopant, through the epitaxial silicon.

Preferably, the tunnels are partially filled with the doped epitaxial silicon such that only the tunnels are filled with a doped epitaxial silicon plug, with the method further comprising filling the plug(s) in the at least one tunnel and the first trench with a material having a higher conductivity than the doped epitaxial silicon to provide low resistivity contact with the doped epitaxial silicon. Suitable high conductivity materials include poly-Si and metals such as Tungsten.

In an embodiment, the first trench is coated with a non-conformal insulating material such as a high-density plasma (HDP) oxide prior to the doped epitaxial silicon growth step to isolate the formed conductor from neighboring silicon. This is particularly advantageous in high voltage applications where such isolation is essential for the correct functioning of the semiconductor device.

At this point, it is emphasized that although the present invention is particularly directed to the formation of a buried conductive structure in the semiconductor substrate as described above, because the formation of such a structure is neither disclosed nor suggested in the prior art, the above method of the present invention may also be used to form other types of buried layers such as buried insulating layers.

For instance, the first trench may surround the other trenches of said plurality of trenches, and the step of forming the local buried layer may comprise filling the at least one tunnel with an oxide such that a local SOI structure may be formed in the substrate. It is pointed out that the method of the present invention holds an important advantage over the method disclosed in U.S. patent application No. 2003/0168711 A1, wherein the SOI area defining trench is formed in a separate step, wherein this trench has to be formed such that it dissects rather than surrounds the buried layer, thus yielding buried regions outside the SOI region surrounded by this trench. Such redundant buried regions are avoided with the method of the present invention because all the trenches are formed in a single step.

According to another aspect of the present invention, there is provided a semiconductor device comprising a substrate having a local buried layer, said layer having an end surface in contact with a filled trench having a width preventing sealing of the unfilled trench in a silicon migration anneal step. Such a device can be more cheaply manufactured than prior art devices having buried layers.

Typically, the local buried layer comprises at least one substantially tubular tunnel extending from the filled trench in case of separate tunnels, or a plurality of partially merged tubular tunnels extending from the filled trench. This shape profile is indicative of the method of the present invention, and distinguishes the device of the present invention from the device disclosed in U.S. Pat. No. 7,019,364 B1, where the merged tubular tunnels extend in parallel with the filled trench.

In a preferred embodiment, the local buried layer comprises a doped epitaxial silicon plug, said plug and trench being filled with a material having a higher conductivity than the doped epitaxial silicon. This yields a semiconductor device having a buried low-ohmic contact to the epitaxial silicon structure that can be manufactured in a simple and cost-effective manner.

The filled trench further comprises an insulating material surrounding the higher conductivity material to isolate the low-ohmic contact from surrounding silicon, thereby making the buried layer suitable for use in high voltage application domains.

### BRIEF DESCRIPTION OF THE DRAWINGS

Embodiments of the invention are described in more detail and by way of non-limiting examples with reference to the accompanying drawings, wherein

FIG. 1 depicts the principles of trench closure by means of Si migration;

FIG. 2a-b depict a part of an embodiment of the method of the present invention;

FIG. 3 depicts an optional part of an embodiment of the method of the present invention;

FIG. 4 depicts a part of a preferred embodiment of the method of the present invention;

FIG. 5 depicts another part of the preferred embodiment of the method of the present invention;

FIG. 6 depicts a part of an alternative embodiment of the method of the present invention;

FIG. 7 depicts a part of a further alternative embodiment of the method of the present invention;

FIG. 8 depicts another part of the further alternative embodiment of the method of the present invention;

FIG. 9 depicts yet another part of the further alternative embodiment of the method of the present invention;

FIG. 10 depicts yet another part of the further alternative embodiment of the method of the present invention;

FIG. 11 depicts yet another part of the further alternative embodiment of the method of the present invention; and

FIG. 12 depicts yet another part of the further alternative embodiment of the method of the present invention.

### DETAIL DESCRIPTION OF THE EMBODIMENTS

It should be understood that the Figures are merely schematic and are not drawn to scale. It should also be understood that the same reference numerals are used throughout the Figures to indicate the same or similar parts.

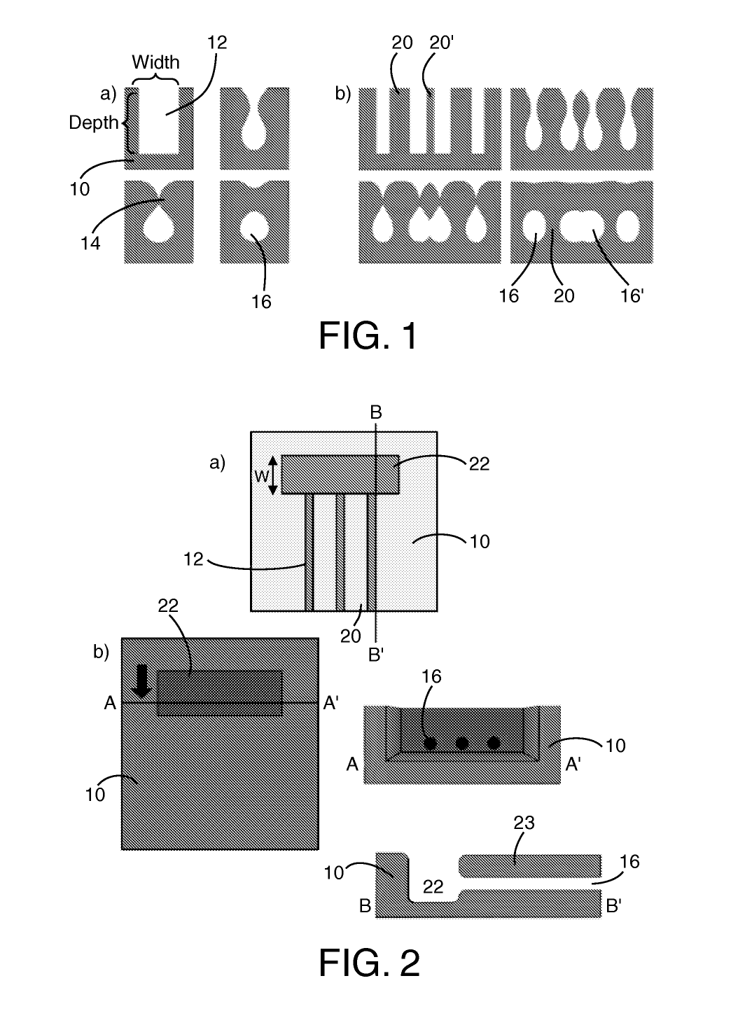

FIG. 1 depicts the principle of buried cavity formation using silicon migration. This process is described in detail in “A New Substrate Engineering for the Formation of Empty Space in Silicon (ESS) Induced by Silicon Surface Migration” by T. Sato et al. in IEDM 1999, pages 517-520.

As depicted in pane a), a trench 12 may be formed in a semiconductor substrate 10 such as a crystalline silicon substrate, with the trench having a width W and a depth D. The width W must be chosen such that, when exposing the trench to an anneal step in a non-oxidizing atmosphere such as a hydrogen ambient at a reduced pressure, e.g. 10 Ton, silicon migration from the sidewalls of the trench 12 to the substrate surface cause the formation of a sealing layer 14 in the top part of the trench 12, ultimately leading to the formation of the tunnel structure 16. In case of a trench having a width W exceeding the critical width, such a trench will not seal and will typically only exhibit some rounding of the trench corners.

The tunnel 16 is typically characterized by a rounded outline, which includes an oval shape as well as a substantially circular shape. As has been explained in for instance U.S. patent application No. 2003/0168711 A1, an oval shape may be converted in a substantially circular shape by extending the duration of the anneal step.

As depicted in pane b), the thickness of side walls 20, 20′ separating parallel trenches 12 will determine the shape of the tunnel 16 to be formed. In case of an anneal process at 1100° C under a hydrogen atmosphere at 10 Torr pressure, a side wall 20 having a thickness in excess of 0.8 micron will prevent all the sidewall material to migrate to the top of the trenches 12, thus yielding a tunnel 16 formed from a single trench 12, whereas a side wall 20′ having a thickness not exceeding 0.8 micron cause the merger of neighboring trenches 12, thus yielding a merged tunnel structure 16′. It will be appreciated that the specified thicknesses of the side walls 20. 20′ relate to the given anneal conditions, and that for different anneal conditions, different thicknesses may apply.

In accordance with an aspect of the present invention, a hard mask (not shown) is deposited on top of the wafer, e.g. by means of a plasma-enhanced chemical vapor deposition (PE-CVD) technique or another suitable deposition technique. Next, a plurality of trenches is patterned into the hard mask using any suitable lithography process, after which the trenches are etched using reactive ion etch (RIE). The result is shown in FIG. 2a, which depicts a top view of the substrate 10, in which a first trench 22 and a plurality of further trenches 12 are formed such that a comb-like structure is formed wherein the first trench 22 forms the backbone and the further trenches 12 form the teeth of the comb. Each further trench 12 is connected to the first trench 22, with the first trench 22 comprising a width W exceeding the aforementioned critical width W, such that the first trench 22 cannot be sealed by silicon migration. Each of the further trenches 12 has a width that is smaller than the critical width W. In FIG. 2a, the thickness of the side walls 20 between neighboring further trenches 12 is chosen such that neighboring further trenches 12 will not merge into a single buried tunnel 16′ during a subsequent anneal step. Although a plurality of further trenches 12 is shown, it will be appreciated that it is equally feasible to form a single further trench 12, in which case the overall trench network is T-shaped.

Next, as shown in FIG. 2b, the further trenches 12 are converted into buried tunnels 16 by an anneal step in a non-oxidizing atmosphere, as previously explained. This may for instance be an anneal step performed at relatively high temperatures and in low pressure hydrogen ambient. The time required for closing the tunnels 16 is depending on the width of the further trenches 12. The topography introduced to the surface of the wafer during the anneal step can be minimized by optimizing the trench depth and the annealing time. For instance, a tunnel 16 having a 500 nm covering portion 23 can be processed in less than 5 minutes at 1100° C. and in 10 Torr hydrogen pressure.

At this point, it is emphasized that the phrase ‘tunnel’ is not intended to imply any specific shape of the buried cavity formed by the silicon migration process. Although the tunnel 16 may have a substantially circular shape, other shapes that can be achieved using a silicon migration process are equally feasible.

As already explained, the first trench 22 will not seal during the Si migration anneal step because of a width exceeding the critical, i.e. maximum allowable width for sealing such trenches. Instead, the first trench 22 will merely exhibit some rounding of its corners because of the silicon migration. An important aspect of the present invention is shown along the B-B′ cross section in FIG. 2b. Because the first trench 22 has a larger width than the further trenches 12, the depth of the first trench 22 achieved in the RIE step is larger than the depth of further trenches 12, which automatically ensures that after the anneal step, the tunnels 16 can be accessed via the first trench 22, which can be seen in the cross section of the substrate 10 along the line A-A′.

FIG. 2 describes a first inventive aspect of the method of the present invention. However, according to a further inventive aspect of the present invention, the one or more tunnels 16 accessible via the first trench 22 are converted into one or more highly doped buried layers, as will be explained in more detail below. It is explicitly stated that for this aspect of the present invention, it is not essential that the one or more tunnels 16 and the first trench 22 are formed in accordance with the method shown in FIG. 2 and described above. In fact, the following aspect of the present may be applied to any buried void that it accessible via a trench such as the first trench 22. For instance, non-limiting examples of forming such an interconnected structure include the methods disclosed in the aforementioned prior art documents U.S. 2003/0168711 A1 and U.S. Pat. No. 7,019,364 B1. Other methods, such as forming a buried void by means of silicon migration and accessing this void by etching an opening to this void, such as for instance is disclosed in U.S. patent application No. 2003/0148588 A1, are equally feasible.

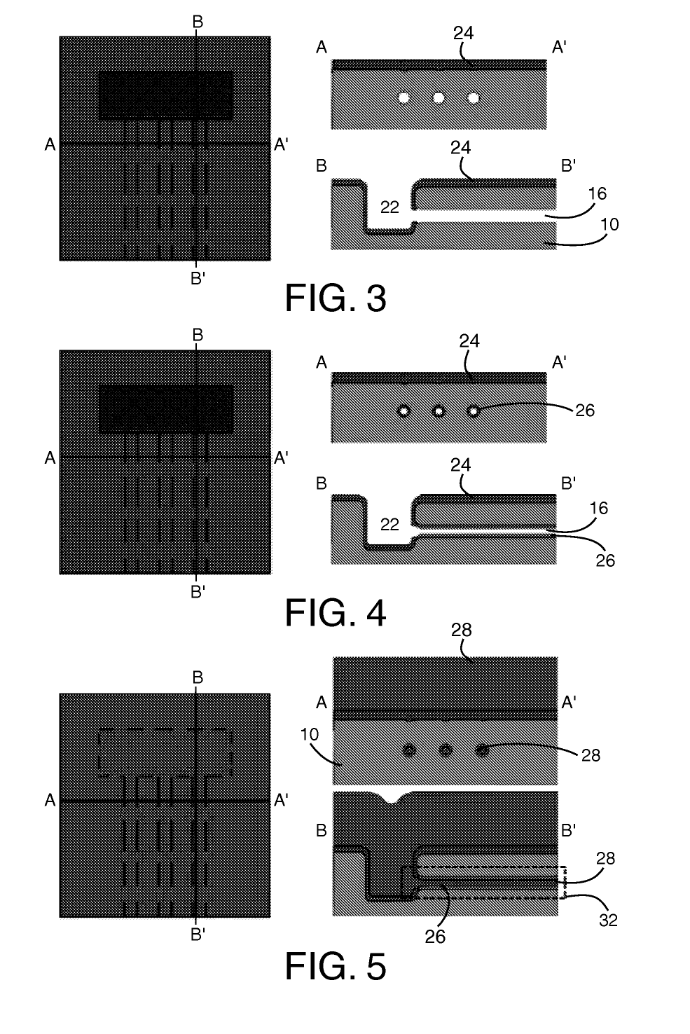

In an embodiment of this aspect of the method of the present invention, shown in FIG. 3, a non-conformal insulating material 24 is deposited over the exposed surfaces of the silicon wafer 10 including the first trench 22, such that all exposed surfaces are protected by this insulating material. Any suitable non-conformal insulating material 24 may be used, such as for instance a HDP oxide. It is pointed out that the inner surfaces of the one or more tunnels 16 are not covered by this insulating layer.

In a next step, shown in FIG. 4, a conformal material such as a doped epitaxial silicon 26 is grown on the unprotected surfaces of the silicon wafer 10, i.e. on the inner surfaces of the one or more tunnels 16. As can be seen in the cross sections along lines A-A′ and B-B′, the doped epitaxial silicon 26 forms a plug inside the tunnels 16. The doped epitaxial silicon 26 may be an n-type doped silicon, which may be grown using conventional epitaxial layer growth techniques. For instance, the epitaxial layer may be grown at relatively low temperature, e.g. between 1020-1120° C, using any suitable dopant. Non-limiting examples of suitable dopants, i.e. impurities, include n-type impurities such as arsenic and phosphorous and p-type impurities such as boron. Such a doped buried epitaxial layer may for instance be used to form a semiconductor device having a vertical p-n junction, with the buried doped epitaxial layer 26 forming the bottom doped layer of such a junction. Such junctions may for instance also be used to form vertical transistors.

In a next step, as shown in FIG. 5, the one or more doped epitaxial silicon plugs 26 are connected to a low-ohmic contact by the deposition of a material 28 having a higher conductivity than the doped epitaxial silicon plugs 26 over the silicon substrate 10 such that the first trench 22 and the remaining unfilled areas of the tunnels 16 are filled with the material 28. Non-limiting examples of such a material 28 include polycrystalline silicon (poly-Si) and metals such as tungsten. These materials may be deposited using any suitable deposition technique. For instance, a tungsten contact may be deposited using a CVD technique. In an embodiment, the tungsten contact consist of three metal layers. First, a thin Ti layer and TiN are deposited to improve the adhesion of surfaces to receive the contact, after which the trench 22 (and tunnel 16 if applicable) is filled with W (tungsten). Alternatively, a low-ohmic contact formed of in-situ highly doped poly-Si may be used. Consequently, a highly doped buried structure 32 is provided which may be driven through a low-ohmic contact formed in the first trench 22. Preferably, the impurity concentrations in the epitaxial plug 26 are in the typical range available for epitaxial processes, e.g. 10¹⁴-10²⁰ atoms/cm³. The higher end of the range, e.g. 10²⁰ atoms/cm³ is suitable for the formation of the low-ohmic contact.

Alternatively, the tunnels 16 may be completely filled with the epitaxial silicon, with the trench 22 being filled with the low-ohmic plug. An anneal step may follow the epitaxial growth step to diffuse the doped impurities through the epitaxial silicon 26.

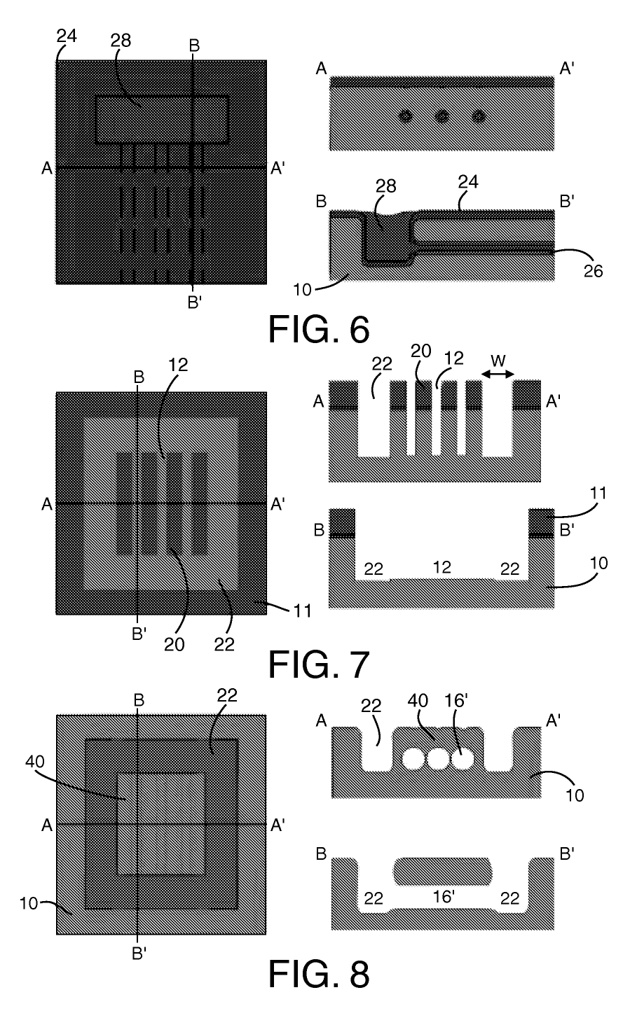

As shown in FIG. 6, excess material 28 may be removed from the upper surface of the silicon wafer 10, e.g. by means of a polishing step such as a chemical-mechanical polishing (CMP) step or by means of a back-etch.

It is emphasized that the deposition step of the non-conformal insulating material 24 shown in FIG. 3 is an optional step, which may be omitted from the formation of the highly doped buried structure 32 in case the low-ohmic contact formed in the first trench 22 does not have to be insulated from the surrounding silicon, e.g. in order to prevent interference between the low-ohmic contact and the surrounding silicon. However, the inclusion of the insulating layer 24 is typically beneficial in high voltage applications requiring vertical p-n junctions or vertical transistors in which non-negligible leakage currents may flow from the low-ohmic contact to the surrounding silicon in the absence of the insulating layer 24.

Now, upon returning to the first inventive aspect of the present invention as shown in FIG. 2a and FIG. 2b and described in the detailed description of these figures, the interconnected plurality of trenches 12 and 22 may also be used to manufacture different types of buried layers in the silicon substrate 10. For instance, a buried insulator region may be formed to define a local SOI region in the substrate 10. This may for instance be achieved as follows.

As shown in FIG. 7, a hard mask 11 is deposited over the silicon substrate 10, e.g. by means of a PE-CVD process as a non-limiting example of a suitable deposition technique, after which the hard mask 11 is patterned using conventional lithography to enable the formation of a plurality of trenches using an etch step such as a RIE step. The plurality of trenches include parallel further trenches 12 and a first trench 22 surrounding the plurality of further trenches 12 such that each trench 12 is connected to the first trench 22 at both ends, as shown in the cross section along the line B-B′. As shown in the cross section along the line A-A′, the thickness of the side walls 20 between the plurality of further trenches 12 is chosen such that the further trenches 12 will not merge into a single buried void in a subsequent silicon migration step, but wherein the resulting silicon walls separating the respective tunnels 16 are quite thin, e.g. approximately 0.1 μm at the thinnest point. Alternatively, the thickness of the side walls 20 may be chosen such that a single buried void formed by merged tunnels is formed.

The width W of the surrounding trench 22 exceeds the aforementioned critical width, such that the surrounding trench 22 will not be sealed in this anneal step. The larger width of the surrounding trench 22 ensures that during the RIE step, this trench becomes deeper than the plurality of parallel trenches 12, as shown in the cross section along the line B-B′.

In a next step, shown in FIG. 8, the hard mask 11 is stripped from the silicon substrate 10 after which the substrate is exposed to an anneal step under a non-oxidizing atmosphere such as an anneal step at 1100° C under a hydrogen ambient at 10 Ton. Other suitable anneal conditions will be apparent to the skilled person. The anneal step triggers the silicon migration of the side walls 20 to the surface of the silicon substrate 10, thereby sealing off the trenches 12 with a silicon cap 40, thus converting the trenches 12 into buried tunnel structures 16.

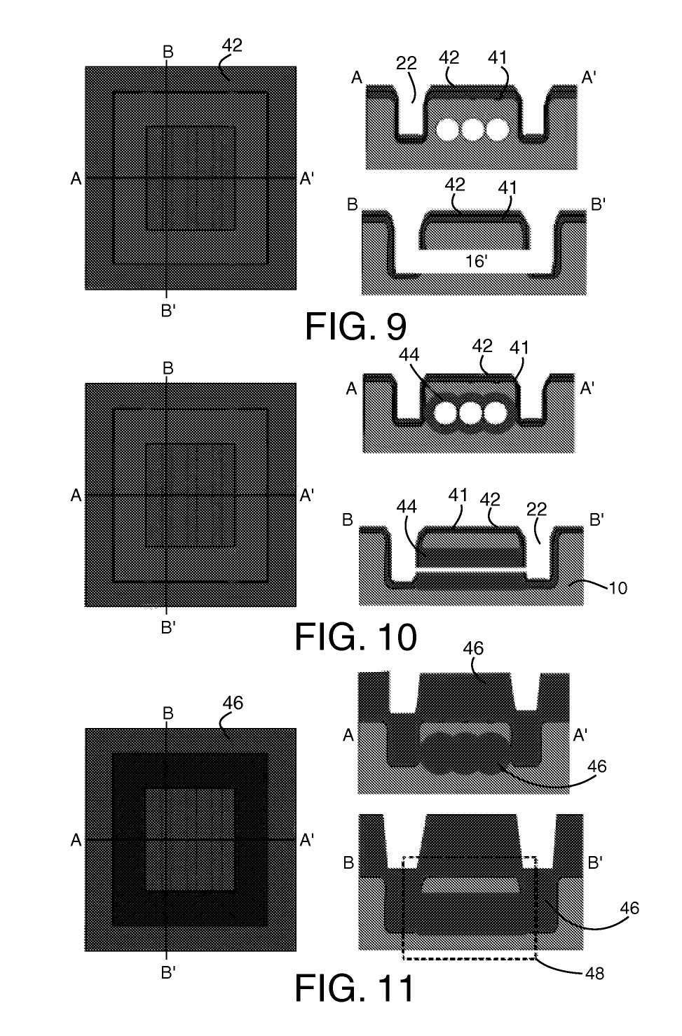

Next, as shown in FIG. 9, the exposed surfaces of the silicon substrate 10, which include the inner surfaces of the surrounding trench 22 but exclude the inner surfaces of the tunnels 16, are protected by the deposition of one or more self-alignment layers such as a non-conformally deposited silicon oxide layer 41 such as a DXZ oxide, followed by a non-conformally deposited nitride layer 42 such as a DXZ nitride (SiNH). Other suitable protection layers and/or protection layer deposition techniques apparent to the skilled person may be used in combination with or instead of the aforementioned oxide layer 41 and nitride layer 42.

Subsequently, the exposed surfaces of the substrate 10, i.e. the sidewalls 44 between the tunnels 16, are completely oxidized, e.g. by means of thermal oxidation, as shown in FIG. 10, after which the nitride layer 42 is stripped away and the tunnels 16 as well as the surrounding trench 22 is filled with an oxide 46 shown in FIG. 11, which may for instance be deposited using a TEOS deposition technique. Consequently, the buried insulator layer defines a SOI region 48 in the silicon substrate 10, which obviates the need to provide expensive SOI wafers.

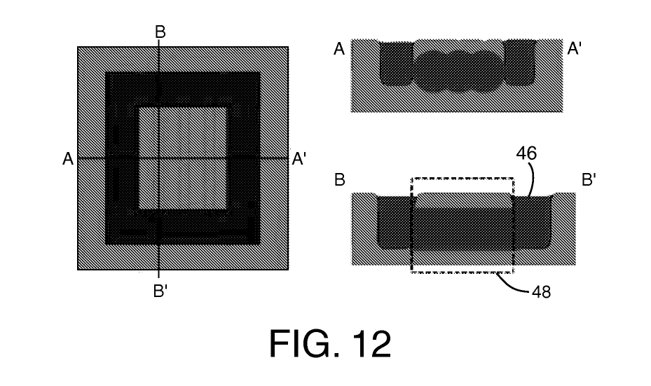

The semiconductor device may be further processed by the removal of any excess oxide 46 from the substrate surface, as shown in FIG. 12. This may be for instance be achieved by means of a CMP step and/or a back-etch. The silicon wafer including the local SOI region 48 may now be further processed using any suitable processing technique, e.g. to form a semiconducting structure in the SOI region 48.

Variations to the above method of forming a local SOI structure 48 will be apparent to the skilled person. For instance, the deposition of nitride layer 42 may be omitted, such that after the deposition of the oxide layer 41, the side walls between the tunnels 16 are removed by means of an isotropic silicon etch, thus yielding a single buried cavity. The non-conformal oxide layer 41 also acts as a support structure to prevent collapse of the single buried cavity. Subsequently, the surrounding trench 22 and the single buried cavity may be filled with an oxide, e.g. using a TEOS deposition step, which has the advantage that the buried insulator can be formed more quickly, because the oxidizing step for oxidizing the side walls between the tunnels 16 is no longer required.

Moreover, it will be appreciated that other types of buried structures may also be formed. For instance, a buried field plate may be formed in the one or more tunnels 16 analogy with the above described formation of a conductive buried layer.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

1. A method of forming a local buried layer in a silicon substrate, comprising:
forming a plurality of trenches in the substrate, including a first trench having a width preventing sealing of the first trench in a silicon migration anneal step and at least one further trench connected to the first trench;
exposing the substrate to said anneal step, thereby converting the at least one further trench by means of silicon migration into at least one tunnel accessible via the first trench; and
forming the local buried layer by filling the at least one tunnel with a material via the first trench.

2. A method according to claim 1, wherein the converting step comprises annealing the silicon substrate in a reduced pressure non-oxidizing atmosphere.

3. A method according to claim 1, wherein forming of the plurality of trenches comprises:
depositing a hard mask over the substrate;
patterning the hard mask;
exposing the substrate to a reactive ion etch; and
removing the hard mask from the substrate.

4. A method according to claim 1, wherein the converting step comprises converting a plurality of trenches into a single tunnel.

5. A method according to claim 1, further comprising coating the first trench with at least one non-conformal material prior to forming the local buried layer.

6. A method according to claim 5, wherein the non-conformal material is a high-density plasma oxide.

7. A method according to claim 1, wherein forming the local buried layer comprises at least partially filling the at least one tunnel with a doped epitaxial silicon.

8. A method according to claim 7, further comprising filling the remaining space in the at least one tunnel and the first trench with a material having a higher conductivity than the doped epitaxial silicon.

9. A method according to claim 1, wherein the first trench surrounds the other trenches of said plurality of trenches.

10. A method according to claim 9, wherein forming the local buried layer comprises filling the at least one tunnel and the first trench with an oxide.

11. A semiconductor device comprising a substrate having a local buried layer, said layer having an end portion in contact with a filled trench, said filled trench having a width preventing sealing of the unfilled trench in a silicon migration anneal step.

12. The semiconductor device according to claim 11, wherein the local buried layer comprises at least one substantially tubular tunnel extending from the filled trench.

13. The semiconductor device according to claim 11, wherein the at least one tunnel comprises a plurality of partially merged tunnels.

14. The semiconductor device according to claim 11, wherein the local buried layer comprises a doped epitaxial silicon plug, said plug and the trench being filled with a material having a higher conductivity than the doped epitaxial silicon.

15. The semiconductor device according to claim 14, wherein the filled trench further comprises an insulating material surrounding the higher conductivity material.
